(19) United States
(12) Patent Application Publication
(10) Pub. No.: US 2012/0118366 A1
(43) Pub. Date: May 17, 2012

(54) DOUBLE-SIDED LIGHT-COLLECTING ORGANIC SOLAR CELL

(75) Inventors: Jea-Gun Park, Seoul (KR); Su-Hwan Lee, Seoul (KR); Ji-Heon Kim, Ulsan (KR); Dal-Ho Kim, Jeollanam-do (KR)

(73) Assignee: Industry-University Cooperation Foundation Hanyang University, Seoul (KR)

(21) Appl. No.: 13/387,613

(22) PCT Filed: Jul. 7, 2010
(86) PCT No.: PCT/KR2010/004423

§ 371 Date: Jan. 27, 2012

(30) Foreign Application Priority Data
Jul. 30, 2009 (KR) 10-2009-0070107

(51) Int. Cl. H01L 51/44

(52) U.S. Cl. 136/255; 136/263; 136/256

(57) ABSTRACT

Disclosed is a double-sided light-collecting organic solar cell. The double-sided light-collecting organic solar cell comprises: a first light-transmitting electrode; a first photoactive layer disposed on the first light-transmitting electrode; a reflective electrode disposed on the first photoactive layer; a second photoactive layer disposed on the reflective electrode; and a second light-transmitting electrode disposed on the second photoactive layer. According to the present invention, photoactive layers are formed on both sides of a reflective electrode in the middle, and light-transmitting electrodes are formed to enable light to be absorbed at both sides of a cell, to increase the light absorption of the cell and enable the production of a highly efficient organic solar cell.

### TECHNICAL FIELD

The present invention generally relates to an organic solar cell, and more particularly, to a double-sided light-collecting organic solar cell.

### BACKGROUND ART

In the face of recent environmental problems and high oil prices, a vast amount of research has been conducted on developing solar cells with a growing interest in developing clean substitute energy sources. Solar cells refer to semiconductor devices configured to directly convert light energy into electrical energy using a photovoltaic effect. Solar cells may be classified into silicon solar cells, compound semiconductor solar cells, dye-sensitized photoelectric cells, and organic solar cells according to components thereof. Among these, an organic solar cell may be manufactured as a thin device because organic molecules used as a photoactive layer have a high light absorption coefficient, may be manufactured using a simple process and at a low cost of equipment, and may be applied in various fields due to the good flexibility and processibility of polymers. However, since the organic solar cell has a high charge trap density, a short charge lifetime, low charge mobility, and a short diffusion length, the organic solar cell may have low light-collecting efficiency, which may degrade photoelectric conversion efficiency. Accordingly, it may be most important to improve the efficiency of a solar cell to ensure the competitiveness of the organic solar cell in terms of the cost of the generation of electricity.

### DISCLOSURE

### [Technical Solution]

The present invention provides an organic solar cell, which may increase light absorptivity to improve photoelectric conversion efficiency.

According to an exemplary embodiment, a double-sided light-collecting organic solar cell is provided. The double-sided light-collecting organic solar cell includes a first light-transmitting electrode, a first photoactive layer disposed on the first light-transmitting electrode, a reflective electrode disposed on the first photoactive layer, a second photoactive layer disposed on the reflective electrode, and a second light-transmitting electrode disposed on the second photoactive layer.

Each of the first and second light-transmitting electrodes may be an anode, and the reflective electrode may be a cathode.

The double-sided light-collecting organic solar cell may further include at least one of a hole injection layer interposed between the first light-transmitting electrode and the first photoactive layer and a hole injection layer interposed between the second light-transmitting electrode and the second photoactive layer. Also, the double-sided light-collecting organic solar cell may further include at least one of an electron injection layer interposed between the reflective electrode and the first photoactive layer and an electron injection layer interposed between the reflective electrode and the second photoactive layer. Furthermore, the double-sided light-collecting organic solar cell may further include at least one of a hole blocking layer interposed between the reflective electrode and the first photoactive layer and a hole blocking layer interposed between the reflective electrode and the second photoactive layer.

The first and second light-transmitting electrodes may be formed of an indium tin oxide (ITO), fluoride-doped tin oxide (FTO), indium zinc oxide (IZO), aluminium-doped zinc oxide (AZO), zinc oxide (ZnO), or gold (Au) thin film irrespective of each other.

The reflective electrode may be formed of silver (Ag), aluminium (Al), nickel (Ni), copper (Cu), platinum (Pt), palladium (Pd), rhodium (Rh), or an alloy thereof.

In the double-sided light-collecting organic solar cell, the first and second photoactive layers may have a bulk heterojunction structure of an electron donor and an electron acceptor, a double junction structure of an electron donor material layer and an electron acceptor material layer, or a multiple junction structure obtained by sequentially bonding an electron donor material layer, an electron donor-electron acceptor mixture layer, and an electron acceptor material layer.

### [Advantageous Effects]

According to the present invention as described above, photoactive layers may be formed on both sides of a reflective electrode disposed in the middle, and light-transmitting electrodes may be formed to enable light to be absorbed at both sides of a cell, to increase light absorptivity of the cell and improve photoelectric conversion efficiency.

### BRIEF DESCRIPTION OF DRAWINGS

FIG. 1 is a cross-sectional view of a double-sided light-collecting organic solar cell according to an exemplary embodiment of the present invention.

FIGS. 2 through 4 are cross-sectional views of a partial photoactive layer structure of various photoactive layer structures of an organic solar cell.

FIG. 5 is a cross-sectional view of a double-sided light-collecting organic solar cell according to another exemplary embodiment of the present invention.

### MODE FOR EMBODYING INVENTION

The present invention will now be described more fully hereinafter with reference to the accompanying drawings, in which exemplary embodiments of the present invention are shown. This present invention may, however, be embodied in different forms and should not be construed as limited to the embodiments set forth herein. Rather, these embodiments are provided so that this invention is thorough and complete and fully conveys the scope of the present invention to one skilled in the art. Detailed descriptions of well-known functions or components are omitted so as not to unnecessarily obscure the embodiments of the present invention. In the drawings, the thicknesses of layers and regions are exaggerated for clarity. Like numbers refer to like elements throughout the description of the figures.

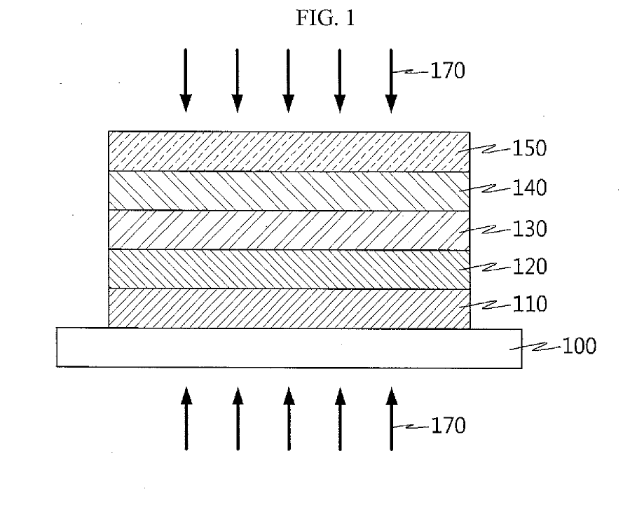

FIG. 1 is a cross-sectional view of a double-sided light-collecting organic solar cell according to an exemplary embodiment of the present invention.

Referring to FIG. 1, a light-transmitting substrate 100 may be a glass substrate or a light-transmitting resin substrate having a high optical transmittance and formed of polyethyleneterephthalate, polystyrene, polycarbonate, polymethylmethacrylate, or polyimide.

Each of a first light-transmitting electrode 110 and a second light-transmitting electrode 150, which are electrodes having a high optical transmittance, may be an anode having a larger work function than a reflective electrode 130. The first and second light-transmitting electrodes 110 and 150 may be identical or different and may be formed of a metal oxide such as an indium tin oxide (ITO), fluoride-doped tin oxide (FTO), indium zinc oxide (IZO), aluminium-doped zinc oxide (AZO) and zinc oxide (ZnO), or a metal such as gold (Au). When the first light-transmitting electrode 110 or the second light-transmitting electrode 150 is formed of a metal thin film, the metal thin film may be formed to such a thickness as to transmit light. In one preferred embodiment, the first light-transmitting electrode 110 may be a metal oxide film and second light-transmitting electrode 150 may be a metal thin film. The first and second light-transmitting electrodes 110 and 150 may be formed by an appropriate method selected from the group consisting of a thermal evaporation method, an electronic beam (e-beam) evaporation method, a radio-frequency (RF) sputtering method, and a magnetron sputtering method.

Each of a first photoactive layer 120 and a second photoactive layer 140 may include an electron donor D and an electron acceptor A. Each of the first and second photoactive layers 120 and 140 may function as a photoelectric conversion layer configured to receive light, separate excitons generated from the electron donor into electrons and holes, and generate current.

The electron donor of the first and second photoactive layers 120 and 140 may be one selected from a high molecular organic semiconductor compound and a small molecular organic semiconductor compound irrespective of each other. The high molecular organic semiconductor compound may be manufactured as a photoactive layer using a casting process, a spin coating process, an inkjet printing process, a screen printing process, a doctor blade process, or a roll-to-roll process. The small molecular organic semiconductor compound may be manufactured as a photoactive layer using a vacuum evaporation process. The high molecular organic semiconductor compound may be, for example, a poly(para-phenylene vinylene) (PPV)-based material or a derivative of polythiophene (PT). The small molecular organic semiconductor compound may be, for example, copper phthalocyanine (CuPc), zinc phthalocyanine (ZnPc), or (2,3,7,8,12,13,17,18-octaethyl-21H,23H-porphyrin)platinum(II) (PtOEP). However, the electron donor of the first and second photoactive layers 120 and 140 is not limited to the above-described materials. An electron acceptor of the first and second photoactive layers 120 and 140 may be, for example, fullerene (C60) or (6,6)-phenyl-C61-butyricacid-methylester (PCBM) or (6,6)-phenyl-C61-butyricacidcholesterylester (PCBCR), which is designed to facilitate dissolution of fullerene in an organic solvent. In another case, the electron acceptor of the first and second photoactive layers 120 and 140 may be a monomer, such as perylene, polybenzimidazole (PBI), or 3,4,9,10-perylene-tetracarboxylic bis-benzimidazole (PTCBI). However, the electron acceptor of the first and second photoactive layers 120 and 140 is not limited to the above-described materials.

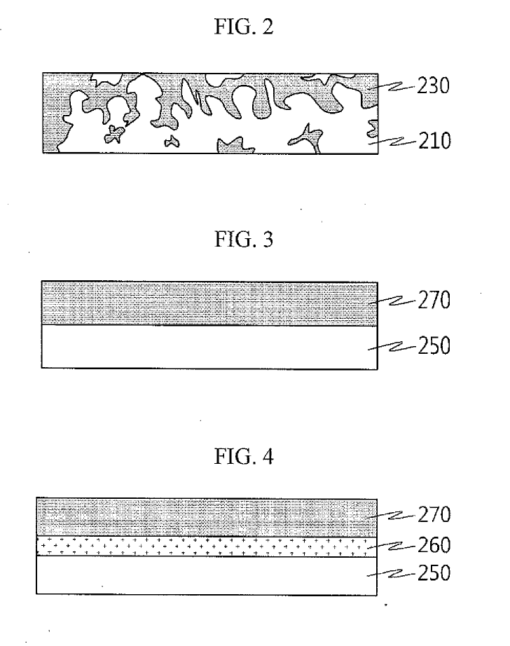

FIGS. 2 through 4 are cross-sectional views of a partial photoactive layer structure of various photoactive layer structures of an organic solar cell.

Referring to FIGS. 2 through 4, a photoactive layer of an organic solar cell may have a bulk heterojunction structure (refer to FIG. 2) of an electron donor 210 and an electron acceptor 230, a double junction structure (refer to FIG. 3) of an electron donor material layer 250 and an electron acceptor material layer 270, or a multiple junction structure (refer to FIG. 4) obtained by sequentially bonding an electron donor material layer 250, an electron donor-electron acceptor mixture layer 260, and an electron acceptor material layer 270.

The first and second photoactive layers 120 and 140 may have an appropriate structure selected from the structures shown in FIGS. 2 through 4 irrespective of each other. However, when the photoactive layers 120 and 140 are formed of a high molecular organic semiconductor compound, each of the photoactive layers 120 and 140 may have the photoactive layer structure of FIG. 2. Also, when the photoactive layers 120 and 140 are formed of a small molecular organic semiconductor compound, each of the photoactive layers 120 and 140 may have the photoactive layer structure of FIG. 3 or FIG. 4.

Referring back to FIG. 1, a reflective electrode 130 may be interposed between the first and second photoactive layers 120 and 140. The reflective electrode 130 may be formed of silver (Ag), aluminium (Al), nickel (Ni), copper (Cu), platinum (Pt), palladium (Pd), rhodium (Rh), or an alloy thereof. Preferably, the reflective electrode 130 may have a reflectivity of at least 50%. The reflective electrode 130 may be formed by an appropriate method selected from the group consisting of a thermal evaporation method, an e-beam evaporation method, an RF sputtering method, or a magnetron sputtering method. Thus, the reflective electrode 130 may be a cathode. The reflective electrode 130 may serve to reflect light transmitted through the photoactive layers 120 and 140 back to the photoactive layers 120 and 140 due to internal reflection to increase optical paths of the photoactive layers 120 and 140. Thus, light absorptivity of the solar cell may be improved.

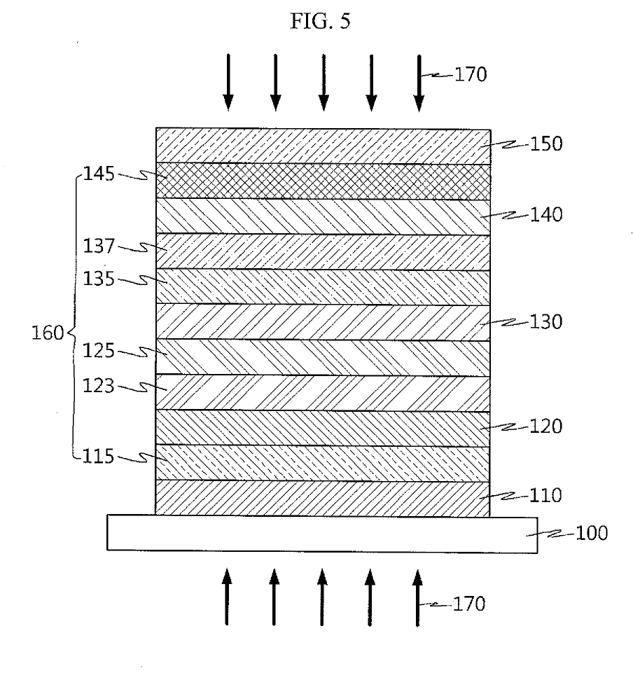

FIG. 5 is a cross-sectional view of a double-sided light-collecting organic solar cell according to another exemplary embodiment of the present invention.

Referring to FIG. 5, as described with reference to FIG. 1, the solar cell may include a light-transmitting substrate 100, a first light-transmitting electrode 110, a first photoactive layer 120, a reflective electrode 130, a second photoactive layer 140, and a second light-transmitting electrode 150. The solar cell may further include a buffer layer 160 interposed between the light-transmitting electrodes 110 and 150 and the photoactive layers 120 and 140 and between the reflective electrode 130 and the photoactive layers 120 and 140. The buffer layer 160 may include a material capable of improving characteristics of an interface between adjacent layers of a device and facilitating separation or transport of charges. The buffer layer 160 may include hole injection layers 115 and 145, electron injection layers 125 and 135, or hole blocking layers 123 and 137 according to main functions thereof.

Although FIG. 5 illustrates the buffer layer 160 including all the hole injection layers 115 and 145, the electron injection layers 125 and 135, and the hole blocking layers 123 and 137, the buffer layer 160 may be formed by appropriately selecting at least one of the hole injection layers 115 and 145, the electron injection layers 125 and 135, and the hole blocking layers 123 and 137 according to purposes as described below in consideration of the efficiency of the solar cell, the amounts and transporting capabilities of electrons and holes, and materials.

The buffer layer 160 may include at least one of the hole injection layer 115 interposed between the first light-transmitting electrode 110 and the first photoactive layer 120 and the hole injection layer 145 interposed between the second light-transmitting electrode 150 and the second photoactive layer 140. The hole injection layers 115 and 145 may function to facilitate transmission of holes generated in the first and second photoactive layers 120 and 140 to the first and second light-transmitting electrodes 110 and 150, respectively. The hole injection layers 115 and 145 may be formed of, for example, 4,4′,4″-tri(N-3-methylphenyl-N-phenylamino)triphenylamine (MTDATA) or poly(3,4-ethylenedioxythiophene):poly(styrenesulfonate) (PEPOT:PSS)

In addition, the buffer layer 160 may include at least one of the electron injection layer 125 interposed between the reflective electrode 130 and the first photoactive layer 120 and the electron injection layer 135 interposed between the reflective electrode 130 and the second photoactive layer 140. The electron injection layers 125 and 135 may function to facilitate transmission of electrons generated in the first and second photoactive layers 120 and 140 to the reflective electrode 130. For example, the electron injection layers 125 and 135 may be formed of, for example, tris(8-hydroxyquinoline) aluminium (Alq3), lithium fluoride (LiF), or a Li complex (8-hydroxy-quinolinato lithium, Liq).

Finally, the buffer layer 160 may include at least one of the hole blocking layer 123 interposed between the reflective electrode 130 and the first photoactive layer 120 and the hole blocking layer 137 interposed between the reflective electrode 130 and the second photoactive layer 140. The hole blocking layers 123 and 137 may function to prevent injection of separated holes and unseparated excitons into the first and second light-transmitting electrodes 110 and 150. For instance, the hole blocking layers 123 and 137 may be formed of bis(2-methyl-8-quinolinolato-N₁,O₈)-(1,1′-biphenyl-4-olato)aluminium (Balq) or 2,9-dimethyl-4,7-diphenyl-1,10-phenanthroline (BCP).

According to the above-described organic solar cell, the photoactive layers 120 and 140 may be disposed on both sides of the reflective electrode 130 serving as a cathode, and the light-transmitting electrodes 110 and 150 may be formed as an uppermost electrode and a lowermost electrode serving as anodes, respectively, so that both top and bottom surfaces of the organic solar cell can absorb solar light 170. Furthermore, the reflective electrode 130 may be disposed within the solar cell so that light unabsorbed by and transmitted through the photoactive layers 120 and 140 may be reflected back to the photoactive layers 120 and 140. Thus, optical paths of the photoactive layers 120 and 140 may be increased to improve light absorptivity.

According to the present invention, a highly efficient organic solar cell having a higher light absorptivity than a conventional organic solar cell in which a light-transmitting electrode is formed on only one surface thereof may be embodied.

While the invention has been shown and described with reference to m certain exemplary embodiments thereof, it will be understood by those skilled in the art that various changes in form and details may be made therein without departing from the spirit and scope of the invention as defined by the appended claims.

1. A double-sided light-collecting organic solar cell comprising:
a first light-transmitting electrode;
a first photoactive layer disposed on the first light-transmitting electrode;
a reflective electrode disposed on the first photoactive layer;
a second photoactive layer disposed on the reflective electrode; and
a second light-transmitting electrode disposed on the second photoactive layer.

2. The solar cell of claim 1, wherein each of the first and second light-transmitting electrodes is an anode, and the reflective electrode is a cathode.

3. The solar cell of any one of claims 1 and 2, further comprising at least one of a hole injection layer interposed between the first light-transmitting electrode and the first photoactive layer and a hole injection layer interposed between the second light-transmitting electrode and the second photoactive layer.

4. The solar cell of any one of claims 1 and 2, further comprising at least one of an electron injection layer interposed between the reflective electrode and the first photoactive layer and an electron injection layer interposed between the reflective electrode and the second photoactive layer.

5. The solar cell of any one of claims 1 and 2, further comprising at least one of a hole blocking layer interposed between the reflective electrode and the first photoactive layer and a hole blocking layer interposed between the reflective electrode and the second photoactive layer.

6. The solar cell of any one of claims 1 and 2, wherein the first and second light-transmitting electrodes are formed of an indium tin oxide (ITO), fluoride-doped tin oxide (FTO), indium zinc oxide (IZO), aluminium-doped zinc oxide (AZO), zinc oxide (ZnO), or gold (Au) thin film irrespective of each other.

7. The solar cell of any one of claims 1 and 2, wherein the reflective electrode is formed of silver (Ag), aluminium (Al), nickel (Ni), copper (Cu), platinum (Pt), palladium (Pd), rhodium (Rh), or an alloy thereof.

8. The solar cell of any one of claims 1 and 2, wherein the first and second photoactive layers have a bulk heterojunction structure of an electron donor and an electron acceptor, a double junction structure of an electron donor material layer and an electron acceptor material layer, or a multiple junction structure obtained by sequentially bonding an electron donor material layer, an electron donor-electron acceptor mixture layer, and an electron acceptor material layer.
